(19) United States
(12) Patent Application Publication
(10) Pub. No.: US 2026/0165102 A1
(43) Pub. Date: Jun. 11, 2026

(54) PLASMA TREATMENT PROCESSES FOR MICROELECTRONIC DEVICE MANUFACTURE

(71) Applicant: Applied Materials, Inc., Santa Clara, CA (US)

(72) Inventors: Ruinan Zhou, Santa Clara, CA (US); Zheng Ju, Sunnyvale, CA (US); Jiajie Cen, San Jose, CA (US); Kevin Kashefi, San Ramon, CA (US); Hsienlung Yang, San Jose, CA (US)

(73) Assignee: Applied Materials, Inc., Santa Clara, CA (US)

(21) Appl. No.: 18/969,948

(22) Filed: Dec. 5, 2024

(51) Int. Cl. H01L 21/768; H01J 37/32

(52) U.S. Cl. CPC H10W 20/076; H01J 37/32082; H01J 37/32522; H01J 37/32816; H10W 20/035; H10W 20/056; H01J 2237/332

(57) ABSTRACT

Plasma treatment processes employed in the manufacture of microelectronic devices are described. Methods of manufacturing interconnect structures as part of a microelectronic device fabrication process are also described. The methods include forming a dielectric layer including at least one feature defining a gap having sidewalls and a bottom on a substrate; treating the substrate with a plasma to form a treated bottom surface; forming a blocking layer on the treated bottom surface by exposing the substrate to a blocking species; selectively depositing a barrier layer on the sidewalls; selectively depositing a metal liner on the barrier layer on the sidewalls; removing the blocking layer; and performing a gap fill process to fill the gap with a gapfill material.

### TECHNICAL FIELD

Embodiments of the disclosure generally relate to the manufacture of microelectronic devices. More particularly, embodiments of the disclosure are directed to plasma treatment processes employed in the manufacture of microelectronic devices.

### BACKGROUND

Multiple challenges impede power and performance improvements when scaling transistors and interconnects to the 3 nm node, 2 nm node, 1.4 nm node, and beyond. Interconnects include metal lines that transfer current within the same device layer and metal vias that transfer current between layers. Pitch reduction narrows the width of both metal lines and metal vias and increases resistance and also increases the voltage drop across a circuit, throttling circuit speed and increasing power dissipation.

While transistor performance improves with scaling, the same cannot be said for interconnect metals. As dimensions shrink, interconnect via resistance can increase by a factor of 10. An increase in interconnect via resistance may result in resistive-capacitive (RC) delays that reduce performance and increases power consumption.

A conventional interconnect structure, such as a copper interconnect structure, includes a barrier layer and/or a metal liner deposited on the sidewalls of a gap that provide a via, the sidewalls made of a dielectric material, providing good adhesion and preventing the copper from diffusing into the dielectric layer. Barrier layers can typically be the largest contributor to via resistance due to their own high resistivity. Past approaches have focused on reducing the thickness of barrier layers or finding barrier layers with lower resistivity to decrease via resistance. Increased via resistance remains an issue, especially in smaller features when barrier layers on sidewalls form an increasing percentage of the via volume.

One approach has been to block or decrease the thickness of the barrier layer on the metal surface at the bottom of the via while the thickness on the dielectric surface at the sidewalls remains. Since the barrier properties of the barrier layer are required between the metallic surface and the dielectric surface, this approach allows for the barrier layer to remain intact, but the reduced thickness on the metallic surface decreases via resistance. These processes are referred to as selective deposition processes.

Selective deposition of materials can be accomplished in a variety of ways. A chemical precursor may react selectively with one surface relative to another surface (e.g., metallic or dielectric). Process parameters such as pressure, substrate temperature, precursor partial pressures, and/or gas flows can be tuned to modulate the chemical kinetics of a particular surface reaction. Another possible scheme involves surface treatments that can be used to activate or deactivate a surface of interest to an incoming deposition precursor. Typically, selective deposition refers to the deposition of a layer on a metallic surface. A reverse selective deposition process deposits a layer on the dielectric surface rather than the metallic surface.

In current interconnect manufacturing processes, one or more surfaces being processed are pre-cleaned prior to further processing, e.g., selective deposition. One of the key challenges experienced after pre-cleaning is the selectivity in which a blocking species, such as an unsaturated hydrocarbon, for example, can be deposited on a metallic surface to prevent subsequent deposition thereon. In particular, selectively depositing the blocking species on molybdenum (Mo), for example, remains a challenge after pre-cleaning, e.g., hydrogen-reduction and physical sputtering. It has been found that the hydrogen-reduction pre-cleaning removes oxygen, leading to a metallic surface, such as a molybdenum (Mo) surface, having low surface density. After the oxygen removal, the density of the metallic surface, such as the molybdenum (Mo) surface is lower than its bulk form, which reduces its electron feedback to a subsequently deposited blocking species and impacts adsorption of the blocking species. It has also been found that physically sputtering argon (Ar), for example, damages the dielectric material of the sidewall.

Accordingly, there is a need for methods for depositing material layers that improve performance of interconnects, for example, reducing via resistance and/or improving deposition selectivity. There is also a need for blocking species that: do not result in integration issues; can provide reduced electrical penalty in the final microelectronic device; can effectively suppress or prevent subsequent deposition of a conductive metal without suppressing or preventing subsequent deposition of underlying interconnect materials.

### SUMMARY

One or more embodiments of the disclosure are directed to a method comprising: treating a substrate including a first surface comprising a dielectric material and a second surface comprising a metallic material with a plasma to form a treated second surface; and exposing the substrate to a blocking species, the blocking species selectively forming on the treated second surface.

Additional embodiments of the disclosure are directed to a method comprising: forming a dielectric layer on a substrate, the dielectric layer including at least one feature defining a gap having sidewalls and a bottom; treating the substrate with a plasma to form a treated bottom surface; and forming a blocking layer on the treated bottom surface by exposing the substrate to a blocking species.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A illustrates a process flow diagram of a method in accordance with one or more embodiments of the disclosure;

FIG. 1B illustrates a schematic cross-sectional view of a substrate including a first surface comprising a dielectric material and a second surface comprising a metallic material in accordance with one or more embodiments of the disclosure;

FIG. 1C illustrates a schematic cross-sectional view of treating the substrate of FIG. 1B with a plasma to form a treated second surface in accordance with one or more embodiments of the disclosure;

FIG. 1D illustrates a schematic cross-sectional view of the substrate including the treated second surface in accordance with one or more embodiments of the disclosure;

FIG. 1E illustrates a schematic cross-sectional view of forming a blocking layer on the treated second surface in accordance with one or more embodiments of the disclosure;

FIG. 2A illustrates a process flow diagram of a method of manufacturing a microelectronic device in accordance with one or more embodiments of the disclosure;

FIG. 2B illustrates a cross-sectional schematic view of a microelectronic device including a gap having sidewalls and a bottom in accordance with one or more embodiments of the disclosure;

FIG. 2C illustrates a cross-sectional schematic view of the gap after treating the substrate with a plasma to form a treated bottom surface in accordance with one or more embodiments of the disclosure;

FIG. 2D illustrates a cross-sectional schematic view of a blocking layer formed on the treated bottom surface in accordance with one or more embodiments of the disclosure;

FIG. 2E illustrates a barrier layer selectively deposited on the sidewalls of the gap in accordance with one or more embodiments of the disclosure;

FIG. 2F illustrates a metal liner selectively deposited on the barrier layer of FIG. 2E in accordance with one or more embodiments of the disclosure;

FIG. 2G illustrates removal of the blocking layer formed in FIG. 2D in accordance with one or more embodiments of the disclosure; and

FIG. 2H illustrates filling the gap in accordance with one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

Spatially relative terms, such as “beneath,” “below,” “lower,” “above,” “upper” and the like, may be used herein for ease of description to describe one element's relationship to another element(s) or feature(s) as illustrated in the Figures. It will be understood that the spatially relative terms are intended to encompass different orientations of the microelectronic device in use or operation in addition to the orientation depicted in the Figures. For example, if the microelectronic device in the Figures is turned over, elements described as “below” or “beneath” other elements would then be oriented “above” the other elements. Thus, the exemplary term “below” may encompass both an orientation of above and below. The microelectronic device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments,” “some embodiments,” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in some embodiments,” “in one embodiment,” or “in an embodiment” in various places throughout this specification are not necessarily referring to the same embodiment of the disclosure. In one or more embodiments, the particular features, structures, materials, or characteristics are combined in any suitable manner.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to “depositing on” or “forming on” a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. In some embodiments, the substrate comprises one or more of doped or undoped crystalline silicon (Si), doped or undoped crystalline silicon germanium (SiGe), doped or undoped amorphous silicon (Si), or doped or undoped amorphous silicon germanium (SiGe). Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The term “on” indicates that there is direct contact between elements. The term “directly on” indicates that there is direct contact between elements with no intervening elements.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

As used herein, the terms “precursor,” “reactant,” “reactive gas,” “reactive species,” and the like are used interchangeably to refer to any gaseous species that can react with the substrate surface.

Sputtering is a physical vapor deposition (PVD) process in which high-energy ions impact and erode a solid target and deposit the target material on the surface of a substrate, such as a semiconductor substrate. In semiconductor fabrication, the sputtering process is usually accomplished within a semiconductor fabrication chamber also known as a PVD processing chamber or a sputtering chamber. Sputtering has long been used for the deposition of metals and related materials in the fabrication of semiconductor integrated circuits.

Typically, the sputtering chamber comprises an enclosure wall that encloses a process zone into which a process gas is introduced, a gas energizer to energize the process gas, and an exhaust port to exhaust and control the pressure of the process gas in the chamber. The chamber is used to sputter deposit a material from a sputtering target onto the semiconductor substrate. In the sputtering processes, the sputtering target is bombarded by energetic ions, such as a plasma, causing material to be knocked off the target and deposited as a film on the semiconductor substrate.

A typical semiconductor fabrication chamber has a target assembly including disc-shaped target of solid metal or other material supported by a backing plate that holds the target. To promote uniform deposition, the PVD chamber may have an annular concentric metallic ring, which is often called a shield, circumferentially surrounding the disc-shaped target.

Plasma sputtering may be accomplished using either DC sputtering or RF sputtering. Plasma sputtering typically includes a magnetron positioned at the back of a sputtering target including two magnets of opposing poles magnetically coupled at their back through a magnetic yoke to project a magnetic field into the processing space to increase the density of the plasma and enhance the sputtering rate from a front face of the target. Magnets used in the magnetron are typically closed loop for DC sputtering and open loop for RF sputtering.

As used herein, the term “chemical vapor deposition” refers to the exposure of at least one reactive species to deposit a layer of material on the substrate surface. In some embodiments, the chemical vapor deposition (CVD) process comprises mixing the two or more reactive species in the processing chamber to allow gas phase reactions of the reactive species and deposition. In some embodiments, the CVD process comprises exposing the substrate surface to two or more reactive species simultaneously. In some embodiments, the CVD process comprises exposing the substrate surface to a first reactive species continuously with an intermittent exposure to a second reactive species. In some embodiments, the substrate surface undergoes the CVD reaction to deposit a layer having a predetermined thickness. In the CVD process, the layer can be deposited in one exposure to the mixed reactive species or can be multiple exposures to the mixed reactive species with purges between. In some embodiments, the substrate surface is exposed to the first reactive species and the second reactive species substantially simultaneously.

As used herein, “substantially simultaneously” means that most of the duration of the first reactive species exposure overlaps with the second reactive species exposure.

As used herein, the term “purging” includes any suitable purge process that removes unreacted precursor, reaction products and by-products from the process region. The suitable purge process includes moving the substrate through a gas curtain to a portion or sector of the processing region that contains none or substantially none of the reactant. In one or more embodiments, purging the processing chamber comprises applying a vacuum. In some embodiments, purging the processing region comprises flowing a purge gas over the substrate. In some embodiments, the purge process comprises flowing an inert gas. In one or more embodiments, the purge gas is selected from one or more of nitrogen (N₂), helium (He), and argon (Ar). In some embodiments, the first reactive species is purged from the reaction chamber for a time duration in a range of from 0.1 seconds to 30 seconds, for example, before exposing the substrate to the second reactive species.

“Cyclical deposition” or “atomic layer deposition” (ALD) refers to the sequential exposure of two or more reactive species to deposit a layer of material on a substrate surface. The substrate, or portion of the substrate, is exposed separately to the two or more reactive species which are introduced into a reaction zone of a processing chamber. In a time-domain ALD process, exposure to each reactive species is separated by a time delay to allow each compound to adhere and/or react on the substrate surface and then be purged from the processing chamber. These reactive species are said to be exposed to the substrate sequentially. In a spatial ALD process, different portions of the substrate surface, or material on the substrate surface, are exposed simultaneously to the two or more reactive species so that any given point on the substrate is substantially not exposed to more than one reactive species simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive species or reaction by-products from the reaction zone. Alternatively, the purge gas may flow continuously throughout the deposition process so that only the purge gas flows during the time delay between pulses of reactive species. The reactive species are alternatively pulsed until a desired layer or layer thickness is formed on the substrate surface. In either scenario, the ALD process of pulsing compound A, purge gas, compound B and purge gas is a cycle. A cycle can start with either compound A or compound B and continue the respective order of the cycle until achieving a layer with the predetermined thickness.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

Generally, front-end of line (FEOL) refers to the first portion of integrated circuit fabrication, including transistor fabrication, middle-of-line (MOL) connects the transistor and interconnect parts of a chip using a series of contact structures, and back-end of line (BEOL) refers to a series of process steps after transistor fabrication through completion of a wafer. The methods according to one or more embodiments of the disclosure can advantageously be used in MOL and/or BEOL processes.

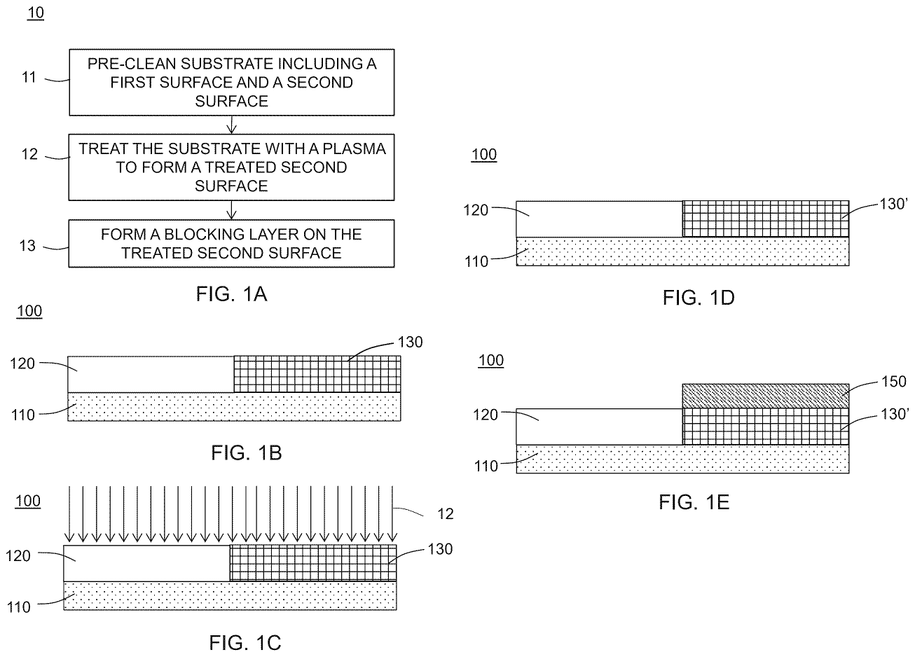

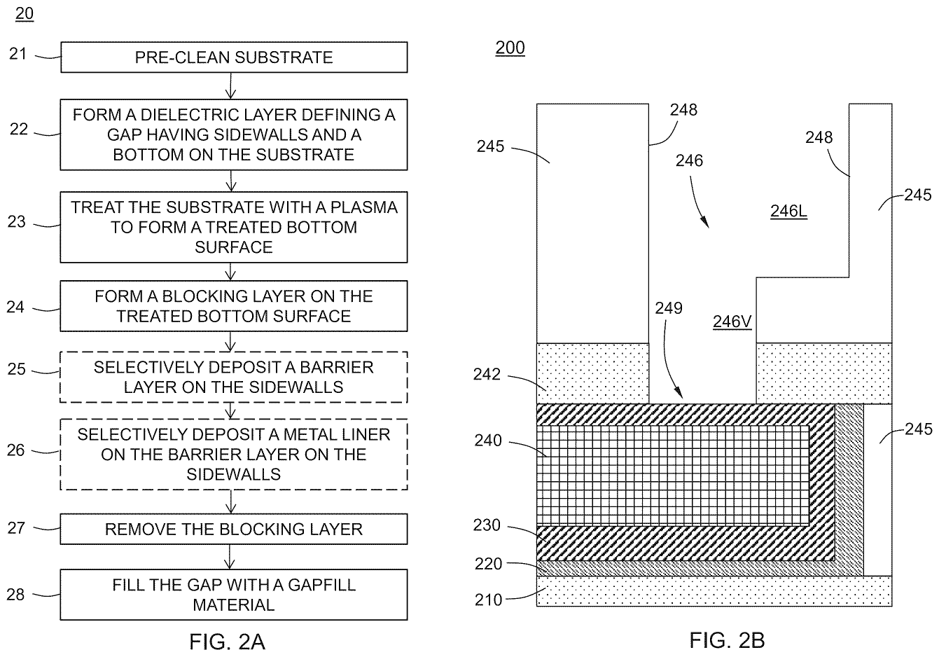

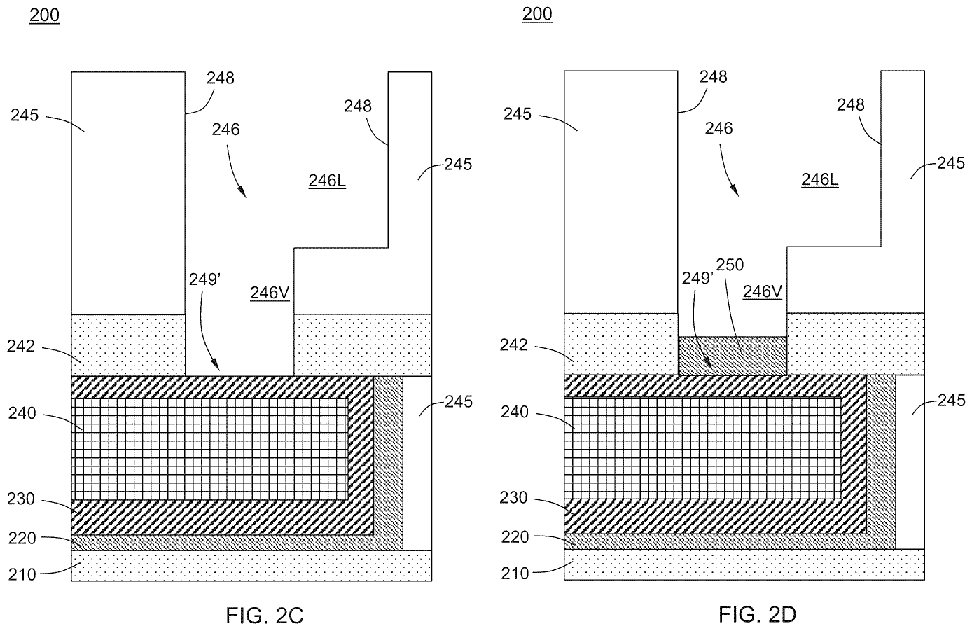

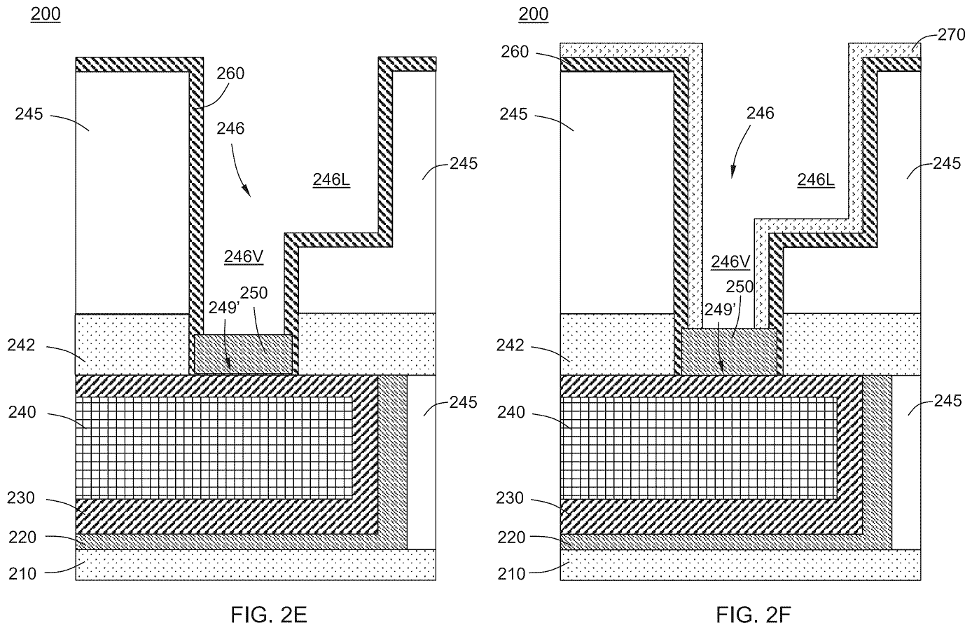

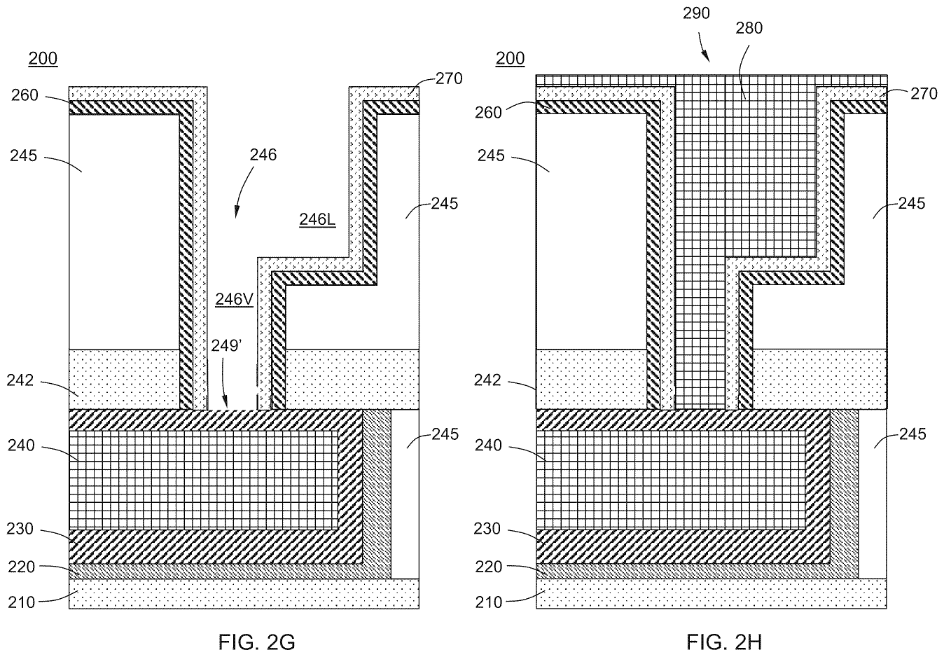

One or more embodiments of the disclosure are directed to plasma treatment processes. Some embodiments of the disclosure are directed to plasma treatment processes employed in the manufacture of electronic devices. Some embodiments of the disclosure are directed to plasma treatment processes employed in the manufacture of, for example, logic devices. Some embodiments of the disclosure are directed to plasma treatment processes employed in the manufacture of, for example, microelectronic devices. The plasma treatment processes are described herein with reference to FIGS. 1A-1E and FIGS. 2A-2H.

FIG. 1A illustrates a process flow diagram of a method 10. FIGS. 1B-1E illustrate schematic cross-sectional views of stages of processing a structure 100 including a substrate 110 in accordance with the method 10. In one or more embodiments, the method 10 comprises, at operation 11, pre-cleaning the substrate 110 including a first surface 120 comprising a dielectric material and a second surface 130 comprising a metallic material (shown in FIG. 1B). In one or more embodiments, keeping the pre-cleaning process under vacuum ensures that no oxide is introduced/formed on the substrate 110 during the method 10. At operation 11, pre-cleaning the substrate 110 removes native oxides from the surface of the substrate 110.

The pre-cleaning process of operation 11 can be any suitable process. In some embodiments, the pre-cleaning process of operation 11 removes polymeric residues and metal oxide from the interconnect and maintains the integrity of the dielectric surface, e.g., the first surface 120. As used herein, the term “substrate 110” can be used to refer to a substrate and/or a pre-cleaned substrate, unless the context clearly indicates otherwise.

One of the key challenges experienced after pre-cleaning is the selectivity in which a blocking species, such as an unsaturated hydrocarbon, for example, can be deposited on a metallic surface to prevent subsequent deposition thereon. In particular, selectively depositing the blocking species on molybdenum (Mo), for example, remains a challenge after pre-cleaning, e.g., hydrogen-reduction and physical sputtering. It has been found that the hydrogen-reduction pre-cleaning removes oxygen, leading to a metallic surface, such as a molybdenum (Mo) surface, having low surface density. After the oxygen removal, the density of the metallic surface, such as the molybdenum (Mo) surface is lower than its bulk form, which reduces its electron feedback to a subsequently deposited blocking species and impacts adsorption of the blocking species. It has also been found that physically sputtering argon (Ar), for example, damages the dielectric material.

At operation 12, the method 10 comprises treating the substrate 110, e.g., the pre-cleaned substrate, with a plasma to form a treated second surface 130′. Advantageously, treating the substrate 110, e.g., the pre-cleaned substrate, with the plasma at operation 12 removes hydrogen and densifies the second surface 130, resulting in the treated second surface 130′.

In accordance with operation 12, the substrate 110 may be treated at any suitable processing conditions, and the processing conditions may vary based upon the application in which the substrate 110 is used.

The substrate 110 may be treated at any suitable temperature during operation 12. In one or more embodiments, the substrate 110 is treated at a temperature in a range of from 100° C. to 350° C.

The substrate 110 may be treated at any suitable pressure during operation 12. In one or more embodiments, the substrate 110 is treated at a pressure in a range of from 100 mTorr to 30 Torr.

The substrate 110 may be treated for any suitable duration of time during operation 12. In some embodiments, the substrate 110 treated for a time period in a range of from 1 second to 60 seconds.

In one or more embodiments, in accordance with operation 12 of the method 10, the plasma comprises one or more of hydrogen (H₂), helium (He), argon (Ar), or krypton (Kr). In one or more embodiments, the plasma consists essentially of one or more of hydrogen (H₂), helium (He), argon (Ar), or krypton (Kr). In one or more embodiments, the plasma consists of one or more of hydrogen (H₂), helium (He), argon (Ar), or krypton (Kr). In one or more embodiments, the plasma includes in a range of from 1 at. % to 90 at. % hydrogen (H₂).

In one or more embodiments, the plasma comprises, consists essentially of, or consists of a mixture of hydrogen (H₂) and argon (Ar). In one or more embodiments where the plasma comprises, consists essentially of, or consists of the mixture of hydrogen (H₂) and argon (Ar), the mixture is delivered in a single step during the time period in the range of from 1 second to 60 seconds.

In one or more embodiments where the plasma comprises, consists essentially of, or consists of the mixture of hydrogen (H₂) and argon (Ar), the mixture includes in a range of from 1 at. % to 90 at. % hydrogen (H₂).

In one or more embodiments, in accordance with operation 12 of the method 10, the plasma is generated by a remote plasma source (RPS), capacitively coupled plasma (CCP) source, inductively coupled plasma (ICP) source, or a microwave plasma source. In one or more specific embodiments, in accordance with operation 12 of the method 10, the plasma comprises argon (Ar) and is generated by a capacitively coupled plasma (CCP) source. In one or more embodiments, in accordance with operation 12 of the method 10, the plasma is generated at an RF power in a range of from 1 watt to 1000 watts. In one or more embodiments, in accordance with operation 12 of the method 10, the plasma is generated using a capacitively coupled plasma (CCP) source at an RF power in a range of from 1 watt to 1000 watts. In one or more embodiments, in accordance with operation 12 of the method 10, the plasma is flowed at a flow rate in a range of from 0 sccm to 4000 sccm.

At operation 13, the method 10 comprises forming a blocking layer 150 on the treated second surface 130′ by exposing the substrate 110 to a blocking species.

Embodiments of the disclosure employ blocking species can be used to form a blocking layer on a surface to suppress or prevent subsequent deposition on that surface. It has been advantageously found that the disclosed blocking species, which will be described in further detail herein, can be used to suppress or prevent subsequent deposition on a metallic surface, e.g., metal lines.

As used herein, the blocking species may be used in, for example, “selective barrier applications” and/or “selective liner applications” as part of the disclosed methods of manufacturing interconnect structures in the manufacture of microelectronic devices. Advantageously, the blocking species of the disclosure are useful in selective barrier applications and/or selective liner applications.

The blocking species advantageously provides reduced electrical penalty in the final microelectronic device. The blocking species can be any suitable species that effectively suppresses or prevents subsequent deposition on a metallic material, including but not limited to, one or more of copper (Cu), cobalt (Co), ruthenium (Ru), tungsten (W), or molybdenum (Mo).

In one or more embodiments, the blocking species comprises a hydrocarbon. The hydrocarbon can include, without limitation, any compound comprising hydrogen (H) atoms and carbon (C) atoms. The hydrocarbon according to one or more embodiments may include substituted or unsubstituted linear hydrocarbon chains, substituted or unsubstituted branched hydrocarbon chains, or substituted or unsubstituted aryl hydrocarbon chains. In one or more embodiments, the hydrocarbon comprises a saturated hydrocarbon. As used herein, a “saturated hydrocarbon” refers to a compound with only single bonds. In one or more embodiments, the hydrocarbon comprises a saturated hydrocarbon having in a range of from 1 to 25 carbon (C) atoms. In one or more embodiments, the saturated hydrocarbon is a substituted or unsubstituted linear hydrocarbon chain, substituted or unsubstituted branched hydrocarbon chain, or substituted or unsubstituted aryl hydrocarbon chain having in a range of from 1 to 25 carbon (C) atoms.

In one or more embodiments, the hydrocarbon comprises an unsaturated hydrocarbon. The unsaturated hydrocarbon can include any compound that includes an unsaturated bond (e.g., a double bond and/or a triple bond), hydrogen (H) atoms, and carbon (C) atoms. In one or more embodiments, the unsaturated hydrocarbon has a general formula of Formula (I) or Formula (II)

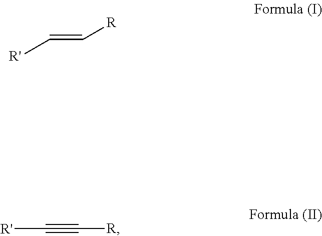

where R and R′ are each independently hydrogen (H), an alkyl group, an alkene group, an alkyne group, an ether group, or an amide group having in a range of from 1 to 25 carbon (C) atoms.

In specific embodiments, the unsaturated hydrocarbon comprises a terminal alkene. As used herein, the phrase “terminal alkene” refers to an unsaturated hydrocarbon having a double bond at the 1 position. For example, in one or more embodiments, the terminal alkene is 1-butene, 1-pentene, 1-hexene, 1-heptene, 1-octene, 1-nonene, 1-decene, 1-undecene, or 1-dodecene. In specific embodiments, the unsaturated hydrocarbon comprises a middle alkene. As used herein, the phrase “middle alkene” refers to an unsaturated hydrocarbon having a double bond at any position other than the 1 position. For example, in one or more embodiments, where the unsaturated hydrocarbon comprises butene, pentene, hexene, heptene, octene, nonene, decene, undecene, or dodecene, the middle alkene is at the 2 position, 3 position, 4 position, 5 position, or 6 position. In one or more embodiments, the middle alkene is a symmetrical alkene. In embodiments where the middle alkene is a symmetrical alkene, the unsaturated hydrocarbon comprises the same number of carbons on each side of the double bond. In specific embodiments where the middle alkene is a symmetrical alkene, the unsaturated hydrocarbon comprises, for example, 3-hexene or 5-decene.

In specific embodiments, the unsaturated hydrocarbon comprises a terminal alkyne. As used herein, the phrase “terminal alkyne” refers to an unsaturated hydrocarbon having a triple bond at the 1 position. For example, in one or more embodiments, the terminal alkyne is 1-butyne, 1-pentyne, 1-hexyne, 1-heptyne, 1-octyne, 1-nonyne, 1-decyne, 1-undecyne, or 1-dodecyne. In specific embodiments, the unsaturated hydrocarbon comprises a middle alkyne. As used herein, the phrase “middle alkyne” refers to an unsaturated hydrocarbon having a triple bond at any position other than the 1 position. For example, in one or more embodiments, where the unsaturated hydrocarbon comprises butyne, pentyne, hexyne, heptyne, octyne, nonyne, decyne, undecyne, or dodecyne, the middle alkyne is at the 2 position, 3 position, 4 position, 5 position, or 6 position. In one or more embodiments, the middle alkyne is a symmetrical alkyne. In embodiments where the middle alkyne is a symmetrical alkyne, the unsaturated hydrocarbon comprises the same number of carbons on each side of the triple bond. In specific embodiments where the middle alkyne is a symmetrical alkyne, the unsaturated hydrocarbon comprises, for example, 3-hexyne or 5-decyne.

One or more embodiments employ blocking species, such as one or more of a substituted or unsubstituted alkyl silyl chloride, a substituted or unsubstituted alkyl halide, a substituted or unsubstituted alkyl thiol, or a substituted or unsubstituted alkyl silane. One or more specific embodiments employ blocking species, such as one or more of dodecyltrichlorosilane, octadecylphosphonic acid, diethyl sulfide, a substituted or unsubstituted aminosilane (such as DIPAS or BDEAS, for example).

Time-Dependent Dielectric Breakdown (TDDB) is measured in electrical tests and refers to the physical process whereby a dielectric stored under a constant electric field, less than the materials breakdown strength, will break down with time. TDDB in low-K dielectrics, for example, is one of the more important failure mechanisms for integrated circuit manufacturing.

The processing conditions for exposing the substrate 110 to the blocking species to form the blocking layer 150 may be controlled and may be varied depending on the composition of the blocking species.

The substrate 110 may be exposed to the blocking species at any suitable pressure for forming the blocking layer 150. In some embodiments, the substrate 110 is exposed to the blocking species at a pressure of less than or equal to about 80 Torr, less than or equal to about 70 Torr, less than or equal to about 60 Torr, less than or equal to about 50 Torr, less than or equal to about 40 Torr, less than or equal to about 30 Torr, less than or equal to about 20 Torr, less than or equal to about 15 Torr, less than or equal to about 10 Torr, or less than or equal to about 5 Torr.

The substrate 110 may be exposed to the blocking species for any suitable time period to form the blocking layer 150 to a predetermined thickness. In some embodiments, the substrate 110 is exposed to the blocking species for a time period in a range of from 1 second to 2,000 seconds. In one or more embodiments, the substrate 110 may be exposed to the blocking species in one or more cycles within the range of from 1 second to 2,000 seconds.

The substrate 110 may be exposed to the blocking species at any suitable temperature to form the blocking layer 150. In some embodiments, the substrate 110 is exposed to the blocking species at a temperature in a range of from 150° C. to 500° C.

The blocking layer 150 may be formed using any suitable deposition technique. In one or more embodiments, the blocking layer 150 is formed in an atomic layer deposition (ALD) chamber.

In one or more embodiments, the method 10 comprises, consists essentially of, or consists of operation 11, operation 12, and operation 13. One or more of the operations of the method 10 can be repeated any suitable number of times depending on the specific application.

Accordingly, it will be appreciated by the skilled artisan that one or more additional operations needed to complete the processing of the substrate 110 are known to the skilled artisan and are within the scope of the disclosure without undue experimentation.

Some embodiments of the disclosure provide methods for improving performance of interconnects. As used herein, and as will be appreciated by the skilled artisan, interconnects generally refer to the wiring in an integrated circuit that connects the transistors to one another and to external connections. Interconnects comprise metal lines that transfer current within the same device layer, and metal vias that transfer current between layers. These metal lines and metal vias are formed with a conductive metal, such as one or more of copper (Cu), cobalt (Co), ruthenium (Ru), tungsten (W), or molybdenum (Mo), in gaps formed within the microelectronic device.

In one or more embodiments, a dielectric layer comprises at least one feature defining a gap having sidewalls and a bottom. In one or more embodiments, the gap includes at least one metal line and at least one metal via. In one or more embodiments, each of the metal lines have a sidewall and a bottom. In one or more embodiments, each of the metal vias have a sidewall and a bottom. As used in this specification and the appended claims, unless specified otherwise, reference to the “bottom of the gap” is intended to mean the bottom of the metal via, which is nearest the substrate surface.

Embodiments of the disclosure provide methods of manufacturing interconnect structures in the manufacture of microelectronic devices. In one or more embodiments, the microelectronic devices described herein comprise at least one top interconnect structure that is interconnected to at least one bottom interconnect structure. Embodiments of the disclosure provide microelectronic devices and methods of manufacturing microelectronic devices that improve performance of interconnects, for example, reducing via resistance.

Methods of manufacturing microelectronic devices are described herein with reference to FIGS. 2A-2H. FIG. 2A illustrates a process flow diagram of a method 20 of manufacturing microelectronic devices 200. FIGS. 2B-2H illustrate stages of manufacture of the microelectronic devices 200 during the method 20.

The method 20 generally refers to a method of manufacturing microelectronic devices and more particularly refer to a method of manufacturing interconnect structures as part of a microelectronic device fabrication process. Accordingly, it will be appreciated by the skilled artisan that one or more additional operations needed to complete the fabrication of a microelectronic device are known to the skilled artisan and are within the scope of the disclosure without undue experimentation.

In one or more embodiments, the method 20 is performed in the order of operations shown in FIG. 2A. The method 20 comprises, at operation 21, pre-cleaning a substrate 210 (shown in FIG. 2B). In one or more embodiments, keeping the pre-cleaning process under vacuum ensures that no oxide is introduced/formed on the substrate 210 during the method 20. At operation 21, pre-cleaning the substrate 210 removes native oxides from the surface of the substrate 210.

Referring to FIGS. 2B-2H, a portion of the microelectronic device 200 is shown during stages of manufacture. In FIG. 2B, the microelectronic device 200 comprises the substrate 210 (i.e., the pre-cleaned substrate), a barrier layer 220 on the substrate 210, a metal layer 230 on the barrier layer 220, a conductive filled gap 240, an etch stop layer 242, and a dielectric layer 245 on the etch stop layer 242. The method 20 includes forming the dielectric layer 245 at operation 22. In one or more embodiments, the dielectric layer 245 is “provided” (i.e., made available for processing) such that operation 22 is not performed.

The dielectric layer 245 comprises at least one feature defining a gap 246 having sidewalls 248 and a bottom 249. It will be appreciated that in one or more embodiments, the conductive filled gap 240 forms a metal line that transfers current within the same device layer.

In one or more embodiments, the substrate 210 is a wafer, for example, a semiconductor substrate. In one or more embodiments, the substrate 210 is an etch stop layer on a wafer. In one or more embodiments, the substrate 210 is an aluminum oxide etch stop layer on a wafer.

In one or more embodiments, the barrier layer 220 comprises tantalum nitride (TaN). In one or more embodiments, the barrier layer 220 comprises tantalum nitride (TaN) formed by ALD.

In one or more embodiments, the metal layer 230 comprises one or more of ruthenium (Ru), copper (Cu), cobalt (cobalt), molybdenum (Mo), tantalum (Ta), or tungsten (W). In one or more embodiments, the metal layer 230 comprises one or more of copper (Cu), cobalt (cobalt), molybdenum (Mo), or tungsten (W). In one or more embodiments, the metal layer 230 comprises molybdenum (Mo). In one or more embodiments, the metal layer 230 comprises molybdenum (Mo) formed by CVD. In one or more embodiments, a portion of the metal layer 230 is etched.

In one or more embodiments, the conductive filled gap 240 comprises one or more of copper (Cu), cobalt (cobalt), ruthenium (Ru), tungsten (W), or molybdenum (Mo). In one or more embodiments, the conductive filled gap 240 comprises molybdenum (Mo). In one or more embodiments, the etch stop layer 242 comprises one or more of aluminum oxide (AlOx), silicon nitride (SiN), or aluminum nitride (AlN).

In one or more embodiments, the dielectric layer 245 comprises a low-K dielectric material. In one or more embodiments, the dielectric layer 245 comprises silicon oxide (SiOₓ). In one or more embodiments, the dielectric layer 245 comprises SiOₓH_{y}(CH_{z}). Further embodiments provide that the dielectric layer 245 comprises porous or carbon-doped SiOₓ. In some embodiments, the dielectric layer 245 is a porous or carbon-doped SiOₓ layer with a K value less than about 5. In other embodiments, the dielectric layer 245 is a multilayer structure. For example, in one or more embodiments, the dielectric layer 245 comprises a multilayer structure having one or more of a dielectric layer, an etch stop layer, and a hard mask layer.

In one or more illustrated embodiments, the dielectric layer 245 comprises at least one feature defining the gap 246 having sidewalls 248 and the bottom 249. The Figures show substrates 210 having a single feature for illustrative purposes; however, those skilled in the art will understand that there can be more than one feature.

As used herein, the term “feature” means any intentional surface irregularity. Suitable examples of features include but are not limited to trenches which have a top, two sidewalls and a bottom, peaks which have a top and two sidewalls. Features can have any suitable aspect ratio (ratio of the depth of the feature to the width of the feature). In some embodiments, the aspect ratio is greater than or equal to about 5:1, 10:1, 15:1, 20:1, 25:1, 30:1, 35:1, 40:1, 50:1, 100:1, or 500:1.

In some embodiments, the at least one feature defines a cylindrical via that, when filled with metal, transfers current between layers, and lines that transfer current within the same device layer. In some embodiments, the at least one feature defines the gap 246 in the dielectric layer 245. In some embodiments, the gap 246 defines a via portion 246V and a line portion 246L.

The bottom 249 of the gap 246 is defined by the metal layer 230. In one or more embodiments, the bottom 249 of the gap 246 and the metal layer 230 comprise the same material. In one or more embodiments, the bottom 249 of the gap 246 comprises one or more of ruthenium (Ru), copper (Cu), cobalt (cobalt), molybdenum (Mo), tantalum (Ta), or tungsten (W). In one or more embodiments, the bottom 249 of the gap 246 comprises one or more of copper (Cu), cobalt (cobalt), ruthenium (Ru), tungsten (W), or molybdenum (Mo). In one or more embodiments, the bottom 249 of the gap 246 comprises molybdenum (Mo).

One of the key challenges experienced in current interconnect manufacturing processes, after pre-cleaning, is the selectivity in which a blocking species, such as an unsaturated hydrocarbon, for example, can be deposited on a metallic surface to prevent subsequent deposition thereon. In particular, selectively depositing the blocking species on molybdenum (Mo), for example, remains a challenge after pre-cleaning, e.g., hydrogen-reduction and physical sputtering. It has been found that the hydrogen-reduction pre-cleaning removes oxygen, leading to a metallic surface, such as a molybdenum (Mo) surface, having low surface density. After the oxygen removal, the density of the metallic surface, such as the molybdenum (Mo) surface is lower than its bulk form, which reduces its electron feedback to a subsequently deposited blocking species and impacts adsorption of the blocking species. It has also been found that physically sputtering argon (Ar), for example, damages the dielectric material.

In one or more embodiments, in accordance with operation 23 of the method 20, the substrate 210 is treated with a plasma to form a treated bottom surface 249′. Advantageously, treating the substrate 210 with the plasma at operation 23 removes hydrogen and densifies the bottom 249, resulting in the treated bottom surface 249′.

In accordance with operation 23, the substrate 210 may be treated at any suitable processing conditions, and the processing conditions may vary based upon the application in which the substrate 210 is used. The substrate 210 may be treated in accordance with operation 23 in the same manner in which the substrate 110 is treated at operation 12, without limitation. Advantageously, treating the substrate 210 at operation 23 increases the density of the bottom 249, e.g., the treated bottom surface 249′.

In one or more embodiments, the blocking layer 250 is formed on the treated bottom surface 249′ in accordance with operation 24 of the method 20. In one or more embodiments, the blocking layer 250 is formed selectively on the treated bottom surface 249′ by exposing the substrate 210 to a blocking species.

It is thought that treating the substrate 210 at operation 23 to form the treated bottom surface 249′ may improve packing density of the blocking layer 250 on the treated bottom surface 249′, and, as a result, improve the blocking properties of the blocking layer 250.

Advantageously, treating the substrate 210 at operation 23 to form the treated bottom surface 249′ improves selectivity of the blocking layer 250 on the treated bottom surface 249′, after pre-cleaning the substrate 210 at operation 21. Advantageously, treating the substrate 210 at operation 23 to form the treated bottom surface 249′ comprising CVD molybdenum (Mo) improves selectivity of the blocking layer 250 on the treated bottom surface 249′ CVD molybdenum (Mo), after pre-cleaning the substrate 210 at operation 21.

It has been advantageously found that the blocking species has a greater affinity for the treated bottom surface 249′ than the bottom 249 without treatment at operation 23, because the treated bottom surface 249′ has a density that is greater than a density of the bottom 249 without treatment at operation 23.

In some embodiments, the processing conditions for exposing the substrate 210 to the blocking species to form the blocking layer 250 may be controlled and may be varied depending on the composition of the blocking species. The blocking layer 250 formed at operation 24 can be formed in the same manner in which the blocking layer 150 is formed in accordance with operation 13, without limitation.

Advantageously, the blocking species described herein are useful in selective barrier applications and/or selective liner applications. Some embodiments of the disclosure are directed to selective barrier applications, e.g., copper (Cu), cobalt (Co), ruthenium (Ru), tungsten (W), and/or molybdenum (Mo) barrier applications.

Referring to FIGS. 2A and 2E, at operation 25 of the method 20, a barrier layer 260 is, optionally, selectively deposited on the sidewalls 248 of the gap 246. In one or more embodiments, the barrier layer 260 has the same properties as the barrier layer 220. In one or more embodiments, the barrier layer 260 does not form on the bottom 149 of the gap 146 (i.e., the treated bottom surface 249′) due to the presence of the blocking layer 250.

The barrier layer 260 may be selectively deposited using any suitable deposition technique. In one or more embodiments, the barrier layer 260 is selectively deposited by atomic layer deposition (ALD).

The barrier layer 260 may have any suitable thickness. In one or more embodiments, the barrier layer 260 has a thickness in a range of from about 2 Å to about 10 Å. In some embodiments, the barrier layer 260 is deposited in a single ALD cycle. In other embodiments, the barrier layer 260 is deposited in from 1 to 20 ALD cycles. In one or more embodiments, each cycle of the 1 to 20 ALD cycles is configured to deposit a thickness of about 0.5 Å of the barrier layer 260.

In one or more embodiments, when the blocking layer 250 is not present, the deposition of the barrier layer 260 is substantially conformal, such that the barrier layer 260 forms on the sidewalls 248 and the treated bottom surface 249′. As used herein, a layer which is “substantially conformal” refers to a layer where the thickness is about the same throughout (e.g., on the top, middle and bottom of sidewalls 248 and on the treated bottom surface 249′). A layer which is substantially conformal varies in thickness by less than or equal to about 5%, 2%, 1% or 0.5%.

In one or more embodiments, the barrier layer 260 is selectively deposited on a portion of the sidewalls 248 and does not form on the treated bottom surface 249′ due to the presence of the blocking layer 250. In one or more embodiments, the barrier layer 260 covers the entirety of the sidewalls 248. In one or more embodiments, the thickness of the barrier layer 260 extends towards the treated bottom surface 249′. In one or more embodiments, the thickness of the barrier layer 260 extends towards the treated bottom surface 249′ and the barrier layer 260 does not form on the treated bottom surface 249′ due to the presence of the blocking layer 250, defining a gap between a bottom portion of the barrier layer 260 and the treated bottom surface 249′. Without intending to be bound by any particular theory, it is thought that minimizing the gap between the bottom portion of the barrier layer 260 and the treated bottom surface 249′ advantageously demonstrates improved selectivity of the blocking layer 250.

In some embodiments, the gap between the bottom portion of the barrier layer 260 and the treated bottom surface 249′ is less than or equal to 6 Angstroms. In some embodiments, the gap between the bottom portion of the barrier layer 260 and the treated bottom surface 249′ is less than or equal to 5 Angstroms. In some embodiments, the gap between the bottom portion of the barrier layer 260 and the treated bottom surface 249′ is less than or equal to 4 Angstroms. In some embodiments, the gap between the bottom portion of the barrier layer 260 and the treated bottom surface 249′ is less than or equal to 3 Angstroms. In some embodiments, the gap between the bottom portion of the barrier layer 260 and the treated bottom surface 249′ is less than or equal to 2 Angstroms. In some embodiments, the gap between the bottom portion of the barrier layer 260 and the treated bottom surface 249′ is less than or equal to 1 Angstrom. In some embodiments, the gap between the bottom portion of the barrier layer 260 and the treated bottom surface 249′ is less than or equal to 0.5 Angstroms. In some embodiments, there is no gap between the bottom portion of the barrier layer 260 and the treated bottom surface 249′.

It has been advantageously found that treating the substrate 210 at operation 23, followed by forming the blocking layer on the treated bottom surface 249′ at operation 24, enhances the selectivity of the barrier layer 260 deposition.

In one or more embodiments, when the barrier layer 260 is formed on the treated bottom surface 249′ and the sidewalls 248, there is a ratio of the thickness of the barrier layer 260 on the sidewalls 248 to the thickness of the barrier layer 260 on the treated bottom surface 249′, the ratio being greater than 6. In one or more, the ratio is greater than 5, greater than 4, greater than 3, greater than 2, or greater than 1.

In one or more embodiments, when the blocking layer 250 is present, the barrier layer 260 has a thickness in a range of from 5 Angstroms to 20 Angstroms on the sidewalls 248 and a thickness of less than or equal to 5 Angstroms on the treated bottom surface 249′. In one or more embodiments, when the blocking layer 250 is present, the barrier layer 260 has a thickness of less than or equal to 4 Angstroms, less than or equal to 3 Angstroms, less than or equal to 2 Angstroms, or less than or equal to 1 Angstrom on the treated bottom surface 249′. In one or more embodiments, when the blocking layer 250 is present, the barrier layer 260 does not form on the treated bottom surface 249′.

The barrier layer 260 may comprise any suitable material that prevents conductive metal, such as, for example, one or more of copper (Cu), cobalt (Co), ruthenium (Ru), tungsten (W), or molybdenum (Mo), from diffusing into the dielectric layer 245. Suitable barrier layers for conductive metal barrier applications, e.g., one or more of copper (Cu), cobalt (Co), ruthenium (Ru), tungsten (W), or molybdenum (Mo) barrier applications include, but are not limited to, tantalum nitride (TaN) and manganese nitride (MnN). In some embodiments, the barrier layer 260 comprises tantalum nitride (TaN) formed by atomic layer deposition (ALD). In some embodiments, ALD of the barrier layer 260 comprising tantalum nitride (TaN) includes exposing the substrate 210 to a tantalum-containing precursor, such as, for example, pentakis (dimethylamino) tantalum (V) (PDMAT) and a nitrogen-containing reactant, such as, for example, ammonia (NH₃).

For some selective barrier applications, suitable dopants include, but are not limited to, ruthenium (Ru), copper (Cu), cobalt (Co), manganese (Mn), aluminum (AI), tantalum (Ta), molybdenum (Mo), niobium (Nb), vanadium (V), or combinations thereof. A plasma treatment can be used after doping to promote the intermetallic compound formation between the matrix and dopant, as well as removing film impurities and improving the density of the barrier layer 260. In other embodiments, post treatment can include, but is not limited to, physical vapor deposition (PVD) treatment, thermal anneal, chemical enhancement, or the like. In some selective barrier applications, a high frequency plasma (defined as greater than about 14 MHz or about 40 MHz or greater) can be used with any inert gas, including, but not limited to, one or more of neon (Ne), hydrogen (H₂), and argon (Ar) gas. In one or more embodiments, to prevent low-K damage, a higher plasma frequency can be used (greater than about 13.56 MHz). In some embodiments, the barrier layer 260 comprises tantalum nitride (TaN) doped with ruthenium (Ru).

In selective barrier applications and selective liner applications, the blocking species selectively adsorbs on the treated bottom surface 249′ as the blocking layer 250. The treated bottom surface 249′ comprises a metallic surface including, but not limited to, one or more of copper (Cu), cobalt (Co), ruthenium (Ru), tungsten (W), or molybdenum (Mo). In some embodiments, the treated bottom surface 249′ comprises molybdenum (Mo). The blocking species advantageously suppresses subsequent deposition, e.g., provide nucleation delay on the treated bottom surface 249′. Advantageously, there is no thermal reaction between the blocking species and the tantalum-containing precursor, e.g., pentakis (dimethylamino) tantalum (V) (PDMAT) and the nitrogen-containing reactant, e.g., ammonia (NH₃), used to form the barrier layer 260 comprising tantalum nitride (TaN).

Some embodiments are directed to selective liner applications. Without intending to be bound by theory, in order to maintain as much volume as possible in a subsequent conductive gap fill process, scaling down the thickness of the metal liner, e.g., metal liner 270, has become critical to meeting resistivity targets.

Referring to FIGS. 2A and 2F, at operation 26 of the method 20, a metal liner 270 is, optionally, selectively deposited on the barrier layer 260. In one or more embodiments, the metal liner 270 has the same properties as the metal layer 230. In one or more embodiments, the metal liner 270 is selectively deposited on the barrier layer 260 on the sidewall 248. In one or more embodiments, the metal liner 270 does not form on the treated bottom surface 249′ due to the presence of the blocking layer 250.

It has been found that selectively depositing the metal liner 270 advantageously reduces resistance of a via as compared to resistance of a via in a microelectronic device where a metal liner is not selectively deposited.

It has been advantageously found that treating the substrate 210 at operation 23, followed by forming the blocking layer on the treated bottom surface 249′ at operation 24, enhances the selectivity of the metal liner 270 deposition.

In one or more embodiments, the metal liner 270 comprises one or more of ruthenium (Ru), cobalt (cobalt), molybdenum (Mo), or tantalum (Ta). In one or more embodiments, the metal liner 270 comprises one or more of a single layer of ruthenium (Ru) or a single layer of cobalt (Co). In one or more embodiments, the metal liner 270 comprises a single layer of ruthenium (Ru). In one or more embodiments, the metal liner 270 comprises a single layer of cobalt (Co). In one or more embodiments, the metal liner 270 comprises a single layer of ruthenium (Ru) that is selectively deposited on the sidewalls 248 and does not form on the treated bottom surface 249′ due to the presence of the blocking layer 250.

In one or more embodiments, when the metal liner 270 comprises a single layer of ruthenium (Ru) selectively deposited on the sidewalls 248 and the blocking layer 250 is formed on the treated bottom surface 249′, there is a ratio of the thickness of the metal liner 270 on the sidewalls 248 to the thickness of the metal liner 270 on the treated bottom surface 249′, the ratio being greater than 3. In one or more embodiments, the ratio of the thickness of the metal liner 270 on the sidewalls 248 to the thickness of the metal liner 270 on the treated bottom surface 249′ is greater than 4, greater than 5, greater than 6 or greater than 7. In one or more embodiments, the metal liner 270 does not form on the treated bottom surface 249′ due to the presence of the blocking layer 250.

In one or more embodiments, when the metal liner 270 comprises a single layer of selectively deposited ruthenium (Ru), the metal liner 270 has a thickness in a range of from 5 Angstroms to 20 Angstroms on the sidewalls 248. In one or more embodiments, when the metal liner 270 comprises a single layer of selectively deposited ruthenium (Ru), the metal liner 270 has a thickness of less than or equal to 5 Angstroms on the treated bottom surface 249′. In one or more embodiments, when the metal liner 270 comprises a single layer of selectively deposited ruthenium (Ru), the metal liner 270 has a thickness of less than or equal to 4 Angstroms, less than or equal to 3 Angstroms, less than or equal to 2 Angstroms, or less than or equal to 1 Angstrom on the treated bottom surface 249′. In one or more embodiments, the metal liner 270 does not form on the treated bottom surface 249′ due to the presence of the blocking layer 250.

In one or more embodiments, the metal liner 270 comprises a multilayer film having a first liner layer comprised of a first metal and a second liner layer comprised of a second metal. Each of the first metal and the second metal independently comprise one or more of ruthenium (Ru), cobalt (cobalt), molybdenum (Mo), or tantalum (Ta). In one or more embodiments, the first liner layer comprises ruthenium (Ru) and the second liner layer comprises cobalt (Co).

In one or more embodiments, when the metal liner 270 comprises the multilayer film having the first liner layer comprised of the first metal and the second liner layer comprised of the second metal, the multilayer film has a combined thickness in a range of 10 to 20 Angstroms on the sidewalls 248. In one or more embodiments, when the first liner layer comprises ruthenium (Ru) and the second liner layer comprises cobalt (Co), the multilayer film has a combined thickness in a range of 5 to 20 Angstroms on the treated bottom surface 249′. In one or more embodiments, when the first liner layer comprises ruthenium (Ru) and the second liner layer comprises cobalt (Co), the multilayer film does not form on the treated bottom surface 249′.

In some embodiments, the multilayer film comprises an alloy of the two metals in a single layer. In one or more embodiments, the multilayer film comprises an alloy of one or more of ruthenium (Ru), cobalt (cobalt), molybdenum (Mo), or tantalum (Ta), such as, for example, an alloy of ruthenium (Ru) and cobalt (cobalt), an alloy of ruthenium (Ru) and molybdenum (Mo), an alloy of ruthenium (Ru) and tantalum (Ta), an alloy of cobalt (cobalt) and molybdenum (Mo), or an alloy of cobalt (Co) and tantalum (Ta).

Advantageously, the multilayer films according to one or more embodiments, which are ultra-thin, e.g., having a thickness of less than or equal to 20 Angstroms, such as in a range of 5 to 20 Angstroms, or in a range of from 10 to 20 Angstroms, provide better interfacial adhesion and mobility between two metals such as between the barrier layer 260 and the conductive metal, e.g., gapfill material 280 used to the fill the gap 246. The multilayer films and methods described according to one or more embodiments, can be used in metal contact, interconnect, and capping applications. The multilayer films according to one or more embodiments are thinner than current liners, which are typically greater than 20 Angstroms and up to 30 Angstroms.

The multilayer films described herein can extend the metal fill and capping applications to advanced nodes, such as enabling conductive metal reflow, e.g., one or more of copper (Cu), cobalt (Co), tungsten (W), ruthenium (Ru), and/or molybdenum (Mo) reflow, in 3 nm node, 2 nm node, 1.4 nm node, and beyond, low resistivity in the middle-of-line (MOL) and back-end of line (BEOL), and memory applications.

The multilayer film can be formed by any suitable deposition techniques and may include one or more deposition techniques. In one or more embodiments, the first liner layer and the second liner layer are formed by the same deposition technique. In one or more embodiments, the first liner layer and the second liner layer are formed by different deposition techniques. The multilayer film can be formed in a single processing chamber or in multiple processing chambers. In one or more embodiments, the multilayer film can be treated by various methods, including thermal treatment, plasma treatment and/or chemical treatment.

In embodiments where the first metal comprises ruthenium (Ru) and the second metal comprises cobalt (Co), the first liner layer is formed by chemical vapor deposition (CVD) including exposing the substrate to

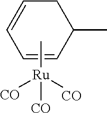

(methylcyclohexadiene tricarbonyl ruthenium) and hydrogen (H₂) followed by CVD of cyclopentadienylcobalt dicarbonyl (CpCo(CO)₂). In selective liner applications, advantageously, there is no thermal reaction between the disclosed blocking species and the hydrogen (H₂) used to form the first liner layer comprising ruthenium (Ru).

In specific embodiments, when the first liner layer comprises ruthenium (Ru) and the second liner layer comprises cobalt (Co), the first liner layer and the second liner layer are formed in the same processing chamber. In specific embodiments, when the first liner layer comprises ruthenium (Ru) and the second liner layer comprises cobalt (Co), the first liner layer and the second liner layer are formed in the same chemical vapor deposition (CVD) chamber.

Referring to FIGS. 2A and 2G, at operation 27 of the method 20, the blocking layer 250 is removed.

In one or more embodiments, the blocking layer 250 is removed after selectively depositing the barrier layer 260 at operation 25, prior to selectively depositing the metal liner 270 at operation 26. In one or more embodiments, the blocking layer 250 is removed after selectively depositing the barrier layer 260 at operation 25 and after selectively depositing the metal liner 270 at operation 26.

In one or more embodiments, removing the blocking layer 250 comprises a plasma treatment process. The plasma treatment process can be any suitable process. In one or more embodiments, the plasma treatment process includes a physical vapor deposition (PVD) process. In one or more embodiments, the plasma treatment comprises flowing one or more of hydrogen (H₂) or argon (Ar). In one or more embodiments, the plasma treatment process increases a density of the barrier layer 260.

Referring to FIGS. 2A and 2H, the method 10 includes performing a gap fill process to fill the gap 246 with the gapfill material 280 at operation 28. The gap fill process can include any suitable deposition technique. In one or more embodiments, the gap fill process comprises a physical vapor deposition (PVD) process.

The gapfill material 280 may include any suitable material, such as a conductive material. In one or more embodiments, the gapfill material 280 comprises one or more of copper (Cu), cobalt (Co), ruthenium (Ru), tungsten (W), or molybdenum (Mo). In one or more embodiments, the gap fill process comprises filling the gap 246 with one or more of copper (Cu), cobalt (Co), ruthenium (Ru), tungsten (W), or molybdenum (Mo) by physical vapor deposition (PVD).

The gapfill material 280 is substantially free of seams and/or voids or free of seams and/or voids. As used in this regard, “substantially free” means that less than about 5%, including less than about 4%, less than about 3%, less than about 2%, less than about 1%, less than about 0.5%, and less than about 0.1% of the total composition of the gapfill material 280 on an atomic basis, comprises seams and/or voids. Advantageously, in one or more embodiments, the gapfill material 280 is free of seams and/or voids.

In one or more embodiments, after filling the gap 246 with the gapfill material 280, a completed interconnect structure, e.g., interconnect structure 290 is formed, such that additional interconnect structures may be formed on top of or below the interconnect structure 290.

In one or more embodiments, the method 20 comprises, consists essentially of, or consists of operation 21, operation 22, operation 23, operation 24, operation 25, operation 26, operation 27, and operation 28. One or more of the operations of the method 20 can be repeated any suitable number of times depending on the specific application.

In one or more embodiments, the methods described herein comprise an optional post-processing operation. The optional post-processing operation can be, for example, a process to modify film properties (e.g., annealing) or a further film deposition process (e.g., additional ALD or CVD processes) to grow additional films. In some embodiments, the optional post-processing operation can be a process that modifies a property of the deposited film/layer.

In some embodiments, the optional post-processing operation comprises annealing the substrate. In some embodiments, the annealing process is performed at temperatures in the range of from 300° C. to 1000° C. The annealing environment of some embodiments comprises one or more of an inert gas (e.g., molecular nitrogen (N₂), argon (Ar)) or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the substrate is annealed for a predetermined time in the range of about 15 seconds to about 90 minutes, or in the range of about 1 minute to about 60 minutes. In some embodiments, annealing the substrate increases the density, decreases the resistivity and/or increases the purity of the layers, such as the barrier layer and/or the metal liner.

In one or more embodiments, one or more of the operations of the methods described herein are performed in situ, without an intervening vacuum break. In one or more embodiments, each of the operations of the methods described are performed in situ, without an intervening vacuum break. In one or more embodiments, one or more of the operations of the methods described herein are performed ex situ, such that one or more of the processes are performed with an intervening vacuum break.

The methods described herein can be performed any suitable processing system. The particular arrangement of processing chambers and components in the processing system can be varied depending on the processing system and should not be taken as limiting the scope of the disclosure.

Processes may generally be stored in the memory of a system controller as a software routine that, when executed by the processor, causes the processing system to perform one or more of the operations of any of the methods described herein. The software routine may also be stored and/or executed by a second processor (not shown) that is remotely located from the hardware being controlled by the processor. Some or all of the methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the processing system operation such that one or more of the operations of any of the methods described herein are performed.

One or more embodiments of the disclosure are directed to a non-transitory computer readable medium including instructions that, when executed by a controller of a processing system, causes the processing system to perform one or more of the operations of any of the methods described herein.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method comprising:
treating a substrate including a first surface comprising a dielectric material and a second surface comprising a metallic material with a plasma to form a treated second surface; and
exposing the substrate to a blocking species, the blocking species selectively forming on the treated second surface.

2. The method of claim 1, further comprising pre-cleaning the substrate prior to treating the substrate.

3. The method of claim 1, wherein the metallic material is molybdenum (Mo).

4. The method of claim 1, wherein the substrate is treated at a temperature in a range of from 100° C. to 350° C.

5. The method of claim 1, wherein the substrate is treated at a pressure in a range of from 100 mTorr to 30 Torr.

6. The method of claim 1, wherein the plasma comprises one or more of hydrogen (H₂), helium (He), argon (Ar), or krypton (Kr).

7. The method of claim 1, wherein the plasma is generated by a remote plasma source (RPS), capacitively coupled plasma (CCP) source, inductively coupled plasma (ICP) source, or a microwave plasma source.

8. The method of claim 1, wherein the plasma is generated at an RF power in a range of from 1 watt to 1000 watts.

9. The method of claim 1, wherein the plasma is flowed at a flow rate in a range of from 0 sccm to 4000 sccm.

10. A method comprising:
forming a dielectric layer on a substrate, the dielectric layer including at least one feature defining a gap having sidewalls and a bottom;
treating the substrate with a plasma to form a treated bottom surface; and
forming a blocking layer on the treated bottom surface by exposing the substrate to a blocking species.

11. The method of claim 10, wherein the bottom comprises a metallic material.

12. The method of claim 11, wherein the metallic material is molybdenum (Mo).

13. The method of claim 10, further comprising selectively depositing a barrier layer on the sidewalls.

14. The method of claim 13, wherein the barrier layer comprises tantalum nitride (TaN).

15. The method of claim 13, further comprising selectively depositing a metal liner on the barrier layer on the sidewalls.

16. The method of claim 15, wherein the metal liner comprises one or more of ruthenium (Ru), cobalt (cobalt), molybdenum (Mo), or tantalum (Ta).

17. The method of claim 16, wherein the metal liner comprises a single layer of ruthenium (Ru).

18. The method of claim 16, wherein the metal liner comprises a multilayer film having a first liner layer comprised of ruthenium (Ru) and a second liner layer comprised of cobalt (Co).

19. The method of claim 15, further comprising removing the blocking layer.

20. The method of claim 19, further comprising filling the gap with a gapfill material comprising one or more of copper (Cu), cobalt (Co), ruthenium (Ru), tungsten (W), or molybdenum (Mo).
